(19) United States
(12) Patent Application Publication
(10) Pub. No.: US 2026/0213749 A1
(43) Pub. Date: Jul. 23, 2026

(54) SUPERCONDUCTING QUANTUM CIRCUIT ELEMENT AND SUPERCONDUCTING QUANTUM COMPUTER

(71) Applicant: TOHOKU UNIVERSITY, Sendai-shi, Miyagi (JP)

(72) Inventors: Taro YAMASHITA, Sendai-shi, Miyagi (JP); Tokunoshin UCHIDA, Sendai-shi, Miyagi (JP)

(21) Appl. No.: 19/142,171

(22) PCT Filed: Dec. 26, 2023
(86) PCT No.: PCT/JP2023/046607

§ 371 Date: Jun. 20, 2025

(30) Foreign Application Priority Data
Feb. 13, 2023 (JP) 2023-019627

(51) Int. Cl. H03K 17/92; G06N 10/20

(52) U.S. Cl. CPC H03K 17/92; G06N 10/20

(57) ABSTRACT

An object of the invention is to provide a magnetic flux type superconducting quantum circuit element and a superconducting quantum computer using the element that can withstand anharmonicity in practical use and achieve high density by not adding a shunt capacitor, and implements improvement in a coherence time. A large-area junction magnetic flux type superconducting quantum circuit element is a superconducting quantum circuit element, the superconducting quantum circuit element is based on a magnetic flux type superconducting quantum circuit element which has three Josephson junctions in one loop and in which an a junction ratio is introduced, the α junction ratio indicating that an area of one Josephson junction among the three Josephson junctions is α times (0.3≤α≤0.7) an area of the other two Josephson junctions having equal areas.

### TECHNICAL FIELD

The present invention relates to a superconducting quantum circuit element (so-called superconducting quantum bit) and a superconducting m computer using the element (so-called superconducting quantum computer).

### BACKGROUND ART

Since a superconducting quantum bit used in a superconducting quantum computer and having a Josephson junction can form a quantum mechanical two-level system, a state (quantum superposition state) in which “0” and “1” are simultaneously taken in one physical system can be implemented, and this is referred to as having quantum parallelism. When a large number of quantum superpositions can be obtained, it will be possible to store a significantly increased number of different states, and thus, this is seen as a promising technology to be used in a future computer field to replace a digital signal process that uses a voltage difference.

This is shown in FIG. 7 showing energy levels of a superconducting quantum bit having a Josephson junction. A horizontal axis represents a phase φ, a vertical axis represents an energy level E, a height described as “n=0” represents a ground state, a height described as “n=1” represents an energy level in a first excited state, and a height described as “n=2” represents an energy level in a second excited state. As shown in FIG. 7, in the superconducting quantum bit having the Josephson junction, an energy difference ε₁₂ between the second excited state and the first excited state and an energy difference 201 between the first excited state and the ground state are adjusted to have different magnitudes. This is because, when an AC electromagnetic wave is applied to control an energy state, in a case where the energy difference ε₁₂ and the energy difference ε₀₁ are different from each other, only the ground state and the first excited state can be obtained, whereas in a case where the energy difference ε₁₂ and the energy difference ε₀₁ are equal to each other, the second excited state may be obtained. In other words, the Josephson junction can be referred to as a circuit element for implementing energy levels at unequal intervals. However, there are several types of superconducting quantum bits having a Josephson junction, and a degree of unequal intervals between energy levels varies depending on the types. The larger the degree of the unequal intervals is, the more stable the quantum bit is. This is referred to as anharmonicity, and is represented by

$$\vert {ε}_{12} - {ε}_{01} \vert ,$$

and
the larger this value, the more stably the quantum bit operates.

A charge type superconducting quantum bit and a magnetic flux type superconducting quantum bit are known as mainstream superconducting quantum bits. (a) of FIG. 8 is a diagram showing a structure of the charge type superconducting quantum bit, and (b) of FIG. 8 is a diagram showing a structure of the magnetic flux type superconducting quantum bit. In both drawings, a thin insulator EI is joined between two superconductors SC to weakly couple the two superconductors. A structure of this coupling is a Josephson junction. An electron pair in a superconducting state passes through the insulator EI by a tunnel effect, and as a result, a current of zero resistance referred to as a Josephson current flows in the Josephson junction. For the superconducting quantum bit, a coherence time, which is a duration of the quantum superposition state, and the anharmonicity for stable operation of the quantum bit are important, but at present, there is a difference that the charge type superconducting quantum bit is advantageous in terms of the coherence time and the magnetic flux type superconducting quantum bit is advantageous in terms of the anharmonicity. Specifically, as shown in (a) of FIG. 8, the charge type superconducting quantum bit has two Josephson junctions (regions defined by two insulators (EI, EI)), but the number of Josephson junctions may be one, and difference between one and two do not significantly affect the coherence time or the anharmonicity. On the other hand, the magnetic flux type superconducting quantum bit shown in (b) of FIG. 8 has a region defined by three Josephson junctions (three insulators (EI1, EI2, and EI3), and a size of a junction area is EI2=EI3 and EI1=αEI2. In this case, α is in a range of 0.3≤α≤0.7, and typically 0.4≤α≤0.5. Although a principle is omitted, introduction of a (referred to as a junction ratio), which is a junction area ratio of the three Josephson junctions, improves the anharmonicity.

When the superconducting quantum bit is put into practical use, first, the coherence time is a problem. This is because a superimposed state of the first excited state and the ground state is lost with time, and the superconducting quantum bit cannot be used as a computer when the lost time is shorter than a time required for state control. In order to cope with an object of improving the coherence time, it is reported that electrostatic energy in the Josephson junction is effectively reduced by introducing a shunt capacitor to improve the coherence time (NPL 1). In addition, it is reported that the coherence time is improved by eliminating noise sources by using an epitaxially grown nitride Josephson junction (NPL 2).

### CITATION LIST

### Non Patent Literature

NPL 1: Fei Yan, Simon Gustavsson, Archana Kamal, Jeffrey Birenbaum, Adam P Sears, David Hover, Ted J. Gudmundsen, Danna Rosenberg, Gabriel Samach, S Weber, Jonilyn L. Yoder, Terry P. Orlando, John Clarke, Andrew J. Kerman & William D. Oliver, “The flux qubit revisited to enhance coherence and reproducibility”, Nature Communications, 3 Nov. 2016
NPL 2: Sunmi Kim, Hirotaka Terai, Taro Yamashita, Wei Qiu, Tomoko Fuse, Fumiki Yoshihara, Sahel Ashhab, Kunihiro Inomata & Kouichi Semba, “Enhanced coherence of all-nitride superconducting qubits epitaxially grown on silicon substrate”, Communications Materials, 20 Sep. 2021

### SUMMARY OF INVENTION

### Technical Problem

Although the charge type superconducting quantum bit is developed in advance, it is impossible in principle to improve the anharmonicity while ensuring an effective coherence time. As described above, it is known that a magnetic flux type superconducting quantum bit including three Josephson junctions more is advantageous in anharmonicity than the charge type superconducting quantum bit. However, according to NPL 1 and NPL 2, it is confirmed that when a shunt capacitor is added to improve the coherence time, the anharmonicity is reduced even in the magnetic flux type superconducting quantum bit.

In addition, as described in NPL 1 and NPL 2, when the shunt capacitor is added, an increase in a footprint, which is an occupation area occupied by one quantum bit, cannot be avoided, and it is difficult to achieve high density.

Therefore, an object of the invention is to provide a magnetic flux type superconducting quantum circuit element and a superconducting quantum computer using the element that can withstand anharmonicity in practical use and achieve high density by adding no shunt capacitor, and implements improvement in a coherence time.

### Solution to Problem

The large-area junction magnetic flux type superconducting quantum circuit element of the invention has at least the following configurations.

A large-area junction magnetic flux type superconducting quantum circuit element superconducting quantum circuit element is a superconducting quantum circuit element, the superconducting quantum circuit element is based on a magnetic flux type superconducting quantum circuit element which has three Josephson junctions in one loop and in which an a junction ratio is introduced, the α junction ratio indicating that an area of one Josephson junction among the three Josephson junctions is α times an area of the other two Josephson junctions having equal areas, and a junction cross-sectional area of each of the three Josephson junctions is set to be large as β times a junction cross-sectional area of the magnetic flux type superconducting quantum circuit element as a base while maintaining the α junction ratio, thereby improving a coherence time. However, α satisfies 0.3≤α≤0.7, preferably 0.4≤α≤0.5. A lower limit is α≥0.3, and preferably α≥0.4. An upper limit is α≤0.7, and preferably α≤0.5. β satisfies 2≤β≤200. To describe the upper limit in particular, the line of β≤200 is realistic for the Josephson junction to function.

The large-area junction magnetic flux type superconducting quantum circuit element of the invention is based on a magnetic flux type superconducting quantum circuit element which has three Josephson junctions in one loop and in which an α junction ratio is introduced, the junction ratio indicating that an area of one Josephson junction among the three Josephson junctions is α times (0.3≤α≤0.7) an area of the other two Josephson junctions having equal areas, and a junction cross-sectional area of each of the three Josephson junctions is set to be large as B times (2≤β≤200) a junction cross-sectional area of the magnetic flux type superconducting quantum circuit element as a base while maintaining the α junction ratio, and an area of each of the three Josephson junctions is set to 0.5 μm² or more and 50.0 μm² or less.

Further, the large-area junction magnetic flux type superconducting quantum circuit element of the invention is based on a magnetic flux type superconducting quantum circuit element which has three Josephson junctions in one loop and in which an α junction ratio is introduced, the xx junction ratio indicating that an area of one Josephson junction among the three Josephson junctions is α times (0.3≤α≤0.7) an area of the other two Josephson junctions having equal areas, and a junction cross-sectional area of each of the three Josephson junctions is set to be large as B times (2≤β≤200) a junction cross-sectional area of the magnetic flux type superconducting quantum circuit element as a base while maintaining the α junction ratio. When it is assumed that the shunt-equipped magnetic flux type superconducting quantum circuit element to which a shunt capacitor is added is set to improve a coherence time of the magnetic flux type superconducting quantum circuit element, a junction cross-sectional area of each of the three Josephson junctions is set to be large enough to obtain a value of a combined capacitance equivalent to a combined capacitance of the shunt-equipped magnetic flux type superconducting quantum circuit element, and no shunt capacitor is actually added.

Furthermore, the large-area junction magnetic flux type superconducting quantum circuit element of the invention is based on a magnetic flux type superconducting quantum circuit element which has three Josephson junctions in one loop and in which an α junction ratio is introduced, the α junction ratio indicating that an area of one Josephson junction among the three Josephson junctions is xx times (0.3≤α≤0.7) an area of the other two Josephson junctions having equal areas, and a junction cross-sectional area of each of the three Josephson junctions is set to be large as β times (2≤β≤200) a junction cross-sectional area of the magnetic flux type superconducting quantum circuit element as a base while maintaining the α junction ratio, and the α junction ratio, an area S of the two Josephson junctions having equal areas, and a Josephson critical current density J_{C} are adjusted to prioritize improvement of anharmonicity.

In addition, the large-area junction magnetic flux type superconducting quantum circuit element of the invention is based on a magnetic flux type superconducting quantum circuit element which has three Josephson junctions in one loop and in which an α junction ratio is introduced, the α junction ratio indicating that an area of one Josephson junction among the three Josephson junctions is α times (0.3≤α≤0.7) an area of the other two Josephson junctions having equal areas, and a junction cross-sectional area of each of the three Josephson junctions is set to be β times (2≤β≥200) a junction cross-sectional area of the magnetic flux type superconducting quantum circuit element as a base while maintaining the α junction ratio, and the α junction ratio, an area S of the two Josephson junctions having equal areas, and a Josephson critical current density J_{C} are adjusted to prioritize improvement of the coherence time.

A large-area junction magnetic flux type superconducting quantum computer of the invention has at least the following configuration.

A superconducting quantum computer includes a large-area junction magnetic flux type superconducting quantum circuit element based on a magnetic flux type superconducting quantum circuit element which has three Josephson junctions in one loop and in which an α junction ratio is introduced, the α junction ratio indicating that an area of one Josephson junction among the three Josephson junctions is α times (0.3≤α≤0.7) an area of the other two Josephson junctions having equal areas, and a junction cross-sectional area of each of the three Josephson junctions is set to be large as β times (2≤β≤200) a junction cross-sectional area of the magnetic flux type superconducting quantum circuit element as a base while maintaining the α junction ratio, thereby improving a coherence time.

### BRIEF DESCRIPTION OF DRAWINGS

FIG. 1 is a diagram schematically showing a structure of a magnetic flux type superconducting quantum bit as a premise.

FIG. 2 is a diagram schematically showing a structure of a shunt-equipped magnetic flux type superconducting quantum bit as a premise.

FIG. 3 is a diagram schematically showing a structure of a large-area junction magnetic flux type superconducting quantum bit according to an embodiment of the invention.

FIG. 4 is a diagram schematically showing a structure of a large-area junction magnetic flux type superconducting quantum bit according to another embodiment of the invention.

FIG. 5 is a table for comparing characteristics of embodiments of the invention with those of various superconducting quantum bits in the related art.

FIG. 6 is a diagram showing a superconducting quantum computer according to an embodiment of the invention.

FIG. 7 is a diagram showing energy levels of a superconducting quantum bit.

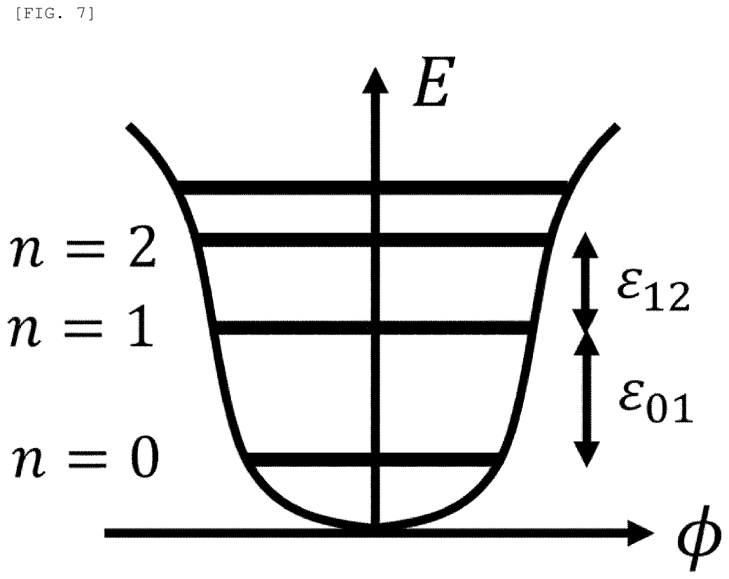

FIG. 8 is a diagram showing a structure of a charge type superconducting quantum bit and a magnetic flux type superconducting quantum bit.

### DESCRIPTION OF EMBODIMENTS

The invention is based on a magnetic flux type superconducting quantum circuit element, has a small footprint, and is capable of achieving high density. In reality, even though a shunt capacitor is not provided, merit equivalent to a case where the shunt capacitor is provided can be obtained. From this viewpoint, the invention can be referred to as a self-shunted magnetic flux type superconducting quantum circuit element (SSFQ: Self-Shunted Flux Qubit).

In order to understand a technical idea of the invention, understanding significance and problems of providing the shunt capacitor in the magnetic flux type superconducting quantum circuit element is a matter to be settled first, and this will be described first.

Although the following description will be given with reference to the drawings, the following drawings are created for the purpose of explanation, and members unnecessary for the description may not be intentionally illustrated for easy understanding. In addition, members may be intentionally illustrated in a large or small size for the sake of description, and are not illustrated in an accurate scale.

### (Magnetic Flux Type Superconducting Quantum Bit as Premise)

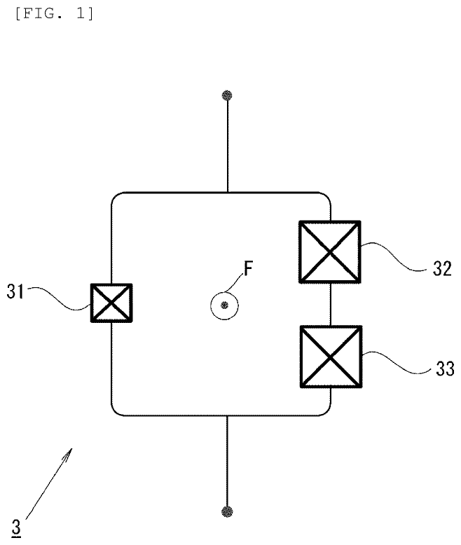

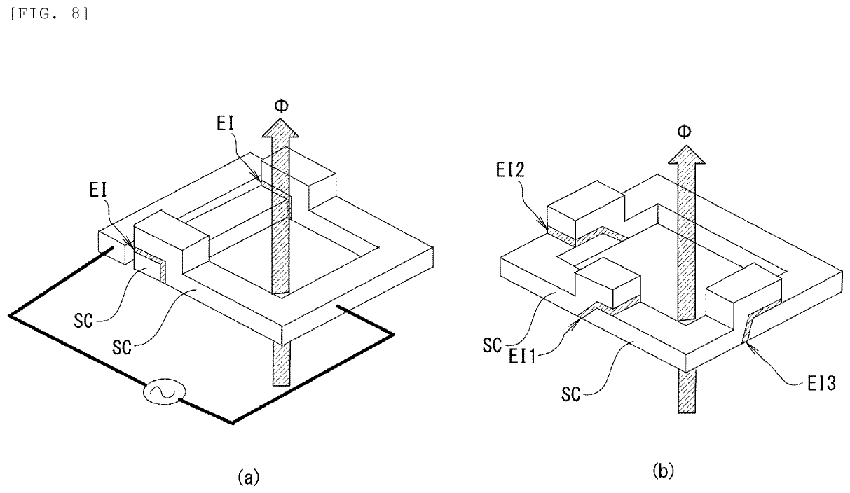

FIG. 1 is a diagram schematically showing a structure of a magnetic flux type superconducting quantum bit 3 in (b) of FIG. 8. The magnetic flux type superconducting quantum bit 3 has a form in which a magnetic flux F penetrates a loop formed by three Josephson junctions of a first Josephson junction 31, a second Josephson junction 32, and a third Josephson junction 33. Among these, a junction cross-sectional area of the second Josephson junction 32 and a junction cross-sectional area of the third Josephson junction 33 are equal. In addition, a cross-sectional area of the first Josephson junction 31 is α times (where 0.3≤α≤ 0.7) the cross-sectional areas of the second Josephson junction 32 and the third Josephson junction 33, and the first Josephson junction 31 has the cross-sectional area smaller than those of the second Josephson junction 32 and the third Josephson junction 33. An area ratio of the Josephson junction is referred to as an a junction ratio.

Incidentally, the Josephson junction can be considered to have two types of energy. One is junction energy E_{J} shown in [Math. 1].

$${E}_{J} = \frac{{Φ}_{0}}{2 π} {I}_{C} ∝ {J}_{C} S \qquad [ Math . 1 ]$$

Here, I_{C} is a Josephson critical current, and Φ₀ is a magnetic flux quantum. J_{C} is a Josephson critical current density, and S is a junction cross-sectional area.

The junction energy is a specific property of a superconductor. Since the Josephson junction sandwiches a thin insulator, a current having zero resistance can flow due to a tunnel effect. Here, a limit of the current that can flow is the Josephson critical current I_{C}.

On the other hand, the Josephson junction can be regarded as a capacitor since an insulator is sandwiched between metals. That is, the other one of the two types of energy of the Josephson junction is electrostatic energy E_{C} represented by [Math. 2].

$${E}_{C} = \frac{{e}^{2}}{2 C} \qquad [ Math . 2 ]$$

Here, C is an electrostatic capacitance, and e is an elementary charge.

In a charge type superconducting quantum bit, it is known that E_{J}/E_{C}, which is a ratio of the two types of energy, determines a charge noise resistance. The larger the ratio, the higher the charge noise resistance. A coherence time tends to increase as the charge noise resistance becomes higher. That is, E_{J}/E_{C}, which is the ratio of the energy, is an index that gives a magnitude of the coherence time.

On the other hand, it is known that when E_{C} is reduced, anharmonicity is also reduced. However, such a relationship between E_{C} and the anharmonicity is shown as a strong tendency in the charge type superconducting quantum bit, and this tendency is not shown as strongly in the magnetic flux type superconducting quantum bit. Therefore, as a method for improving the coherence time of the magnetic flux type superconducting quantum bit, it is conceivable to add a shunt capacitor which is also adopted to the charge type superconducting quantum bit.

### (Shunt-Equipped Magnetic Flux Type Superconducting Quantum Bit as Premise)

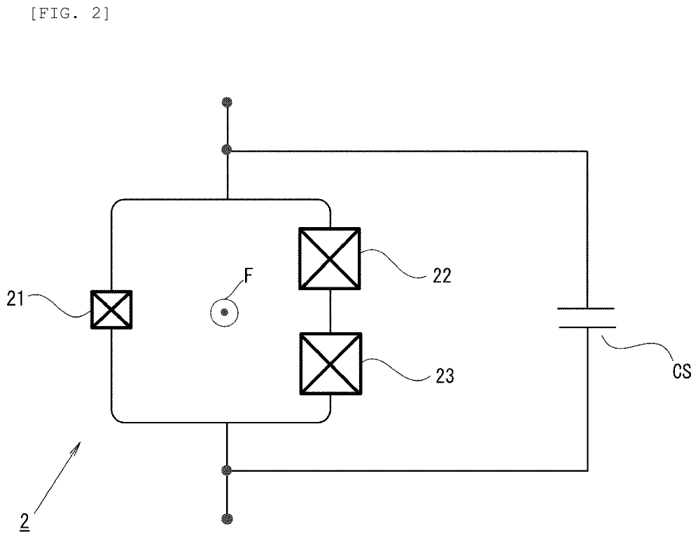

FIG. 2 is a diagram schematically showing a structure of a shunt-equipped magnetic flux type superconducting quantum bit 2. The shunt-equipped magnetic flux type superconducting quantum bit 2 has a form in which the magnetic flux F penetrates a loop formed by three Josephson junctions of a first Josephson junction 21, a second Josephson junction 22, and a third Josephson junction 23, and this is the same as the structure of the magnetic flux type superconducting quantum bit described above. In addition, the structure is also the same as that of the magnetic flux type superconducting quantum bit in that a junction cross-sectional area of the second Josephson junction 22 and a junction cross-sectional area of the third Josephson junction 23 are equal, and a cross-sectional area of the first Josephson junction 21 is α times (where 0.3≤α≤0.7) the cross-sectional areas of the second Josephson junction 22 and the third Josephson junction 23. A difference from the magnetic flux type superconducting quantum bit is that a shunt capacitor CS is connected in parallel to the loop. By connecting the shunt capacitor CS having a large capacitance, E_{C} shown in [Math. 2] becomes a small value, and thus E_{J}/E_{C}, which is the ratio of two types of energy of the Josephson junction, can take a large value.

E_{J}/E_{C} in the shunt-equipped magnetic flux type superconducting quantum bit can take a value larger than 10, and the coherence time is improved. In addition to this, as described above, in the magnetic flux type superconducting quantum bit, even if E_{C} is reduced, the anharmonicity is not impaired as much as when the shunt capacitor is added to the charge type superconducting quantum bit. However, it is undeniable that the anharmonicity is lower than that of the magnetic flux type superconducting quantum bit. In addition, a greatest weakness of the shunt-equipped magnetic flux type superconducting quantum bit is that it is necessary to separately prepare a connection pattern for providing a capacitor in addition to the loop formed by the Josephson junctions, which leads to an increase in the footprint as described above. Therefore, as a result of intensive studies, the present inventors have proposed an approach of a large-area junction magnetic flux type superconducting quantum bit in which E_{J}/E_{C} is increased without using the shunt capacitor.

### One Embodiment of Invention

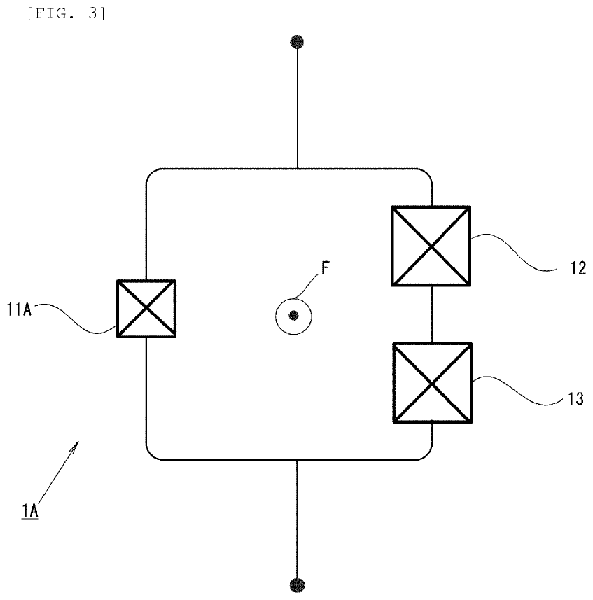

FIG. 3 is a diagram schematically showing a structure of a large-area junction magnetic flux type superconducting quantum bit 1A according to an embodiment of the invention. The large-area junction magnetic flux type superconducting quantum bit 1A has a form in which the magnetic flux F penetrates a loop formed by three Josephson junctions of a first Josephson junction 11A, a second Josephson junction 12, and a third Josephson junction 13, and this is the same as the structure of the magnetic flux type superconducting quantum bit 3 or the structure of the shunt-equipped magnetic flux type superconducting quantum bit 2 described above. In addition, a junction cross-sectional area of the second Josephson junction 12 and a junction cross-sectional area of the third Josephson junction 13 are equal and a cross-sectional area of the first Josephson junction 11A is a times the cross-sectional areas of the second Josephson junction 12 and the third Josephson junction 13 (how to set α will be described later), which is also the same as the structure of the magnetic flux type superconducting quantum bit 3 and the structure of the shunt-equipped magnetic flux type superconducting quantum bit 2.

As illustrated, no shunt capacitor is provided. On the other hand, a difference from the magnetic flux type superconducting quantum bit is that the area of the Josephson junction is increased by β times (β≥2). This feature is a reason for a name of the large-area junction magnetic flux type superconducting quantum bit. Further, according to this feature, E_{J}/E_{C}, which is the ratio of the two types of energy of the Josephson junction, can take a fairly large value of, for example, 300 or more. Further, it is needless to say that there is no problem that the footprint increases.

An approach to change the capacitance of the capacitor is to change a film thickness or a material of an insulating layer included in the Josephson junction, but in this case, the Josephson critical current density may be changed, and thus, increasing the area of the Josephson junction is a method capable of solving the problem. The film thickness of the insulating layer included in the Josephson junction is considered in controlling the Josephson critical current density as described later.

In the large-area junction magnetic flux type superconducting quantum bit 1A, the cross-sectional area of the first Josephson junction 11A, the cross-sectional area of the second Josephson junction 12, and the cross-sectional area of the third Josephson junction 13 are respectively set to be β times the cross-sectional area of the first Josephson junction 31, the cross-sectional area of the second Josephson junction 32, and the cross-sectional area of the third Josephson junction 33 of the magnetic flux type superconducting quantum bit 3 so as to be large enough to obtain a value of a combined capacitance equivalent to a combined capacitance of the shunt-equipped magnetic flux type superconducting quantum bit 2.

Strictly speaking, the value of B is determined by calculating a total numerical value of Hamiltonian describing the quantum bit, but is schematically obtained as follows. In the shunt-equipped magnetic flux type superconducting quantum bit, the combined capacitance is approximately represented by a sum (CS+CJ) of the shunt capacitor CS and a capacitor CJ of the Josephson junction. In the invention, as described above, this is set to the same value in the capacitor of the Josephson junction. In general, since the shunt capacitor CS is often set to be approximately equal to or larger than CJ (CS+CJ≥2CJ), the cross-sectional area of the Josephson junction in the invention is set under a guideline that the cross-sectional area of the Josephson junction is twice or more (β≥2) of a magnetic flux type quantum bit in the related art.

At this time, since the Josephson critical current I_{C} is also β times, E_{J}/E_{C} can be adjusted by adjusting the Josephson critical current density J_{C}, and element characteristics such as the anharmonicity can be designed. Note that the Josephson critical current density J_{C} can be adjusted by the film thickness of the insulating layer included in the Josephson junction and the like.

In the invention, as described above, when α satisfies 0.3≤α≤0.7, which is the same as the structure of the magnetic flux type superconducting quantum bit 3 or the structure of the shunt-equipped magnetic flux type superconducting quantum bit 2, it is possible to operate as the magnetic flux type superconducting quantum bit, but since a condition that the area of the Josephson junction is β times (β≥2) is added, a range of a suitable for improving the anharmonicity may be particularly limited while satisfying the condition. In the invention, when x is in a range of 0.4≤α≤0.5, particularly good performance can be obtained, and a suitable design can be made. Therefore, a lower limit value is preferably α≥0.4, and an upper limit value is preferably α≤0.5. However, as can be understood from the fact that there is a research example for converting an aluminum-based amorphous as a typical example of a composition of the Josephson junctions to a crystalline composition, performance may be maintained due to other factors such as a material, and thus the composition should not be limited to 0.4≤α≤0.5 even in consideration of feasibility.

In addition, a junction area of a normal magnetic flux type superconducting quantum bit is generally smaller than 0.25 μm², but in the invention, the junction area is β times (β≥2) the normal junction area. According to a setting related to a value of the capacitor under the above-described guideline, the area of the Josephson junction is preferably 0.5 μm² or more. On the other hand, an upper limit of B may have a magnitude that allows the superconducting quantum bit to move, but since the area of the Josephson junction is sufficiently movable as long as the area is 50.0 μm² or less, the upper limit of β may be about β times (200≥β) or less. Further, as described above, since a problem of a noise source due to defects can be overcome by the conversion to the crystalline composition, it is expected that a larger β close to 200 can be adopted.

By appropriately adjusting three values of the α junction ratio, the junction area S set to be larger than the junction of the magnetic flux type superconducting quantum bit in the related art, and the Josephson critical current density J_{C}, the large-area junction magnetic flux type superconducting quantum bit can maintain high anharmonicity and implement a long coherence time without providing the shunt capacitor.

Various numerical values such as a size and characteristics of the large-area junction magnetic flux type superconducting quantum bit 1A according to the embodiment of the invention will be described. In the embodiment, α=0.484, and the area of the two Josephson junctions having equal areas is 1.62 μm². Considering that the junction area of the normal magnetic flux type superconducting quantum bit is smaller than 0.25 μm², the junction area is six times or more (β≥6: β is a ratio to the Josephson junction cross-sectional area of the magnetic flux type superconducting quantum bit).

By separately adjusting the Josephson critical current density J_{C}, the large-area junction magnetic flux type superconducting quantum bit 1A according to the embodiment of the invention to which the element size, the α junction ratio, and the junction area S described above are given can implement the characteristics that a minimum junction area is 0.78 μm², the critical current density is 11.0 A/cm², the anharmonicity is 1.0 GHZ, and a quantum bit energy change (the smaller the change, the higher the coherence) with respect to a magnetic flux fluctuation, which is an index of a magnetic flux noise resistance affecting the coherence time, is 24.4 MHz. Although the anharmonicity is not as high as the magnetic flux type superconducting quantum bit, this value is practically acceptable. In addition, since a large shunt capacitor having a side of several tens to several 100 μm as in the shunt-equipped magnetic flux type superconducting quantum bit is not necessary, it can be seen that the footprint can be significantly reduced.

Further, a minimum size (diameter or one side) of the Josephson junction is usually 0.5 μm or less, whereas in the embodiment, a diameter in a case of a circular junction is 1.0 μm (area of Josephson junction is 0.78 μm²) (even in the case of the invention, the area is 0.5 μm², and a diameter in the case of the circular junction is 0.8 μm or more). In the related art, the Josephson junction can be formed only by an electron beam lithography apparatus or the like, but in the embodiment (or the invention), the Josephson junction can be formed by a more inexpensive exposure apparatus or the like, and thus, the Josephson junction can be formed at low cost.

Note that the Josephson junction may have any shape, such as a square, a rectangle, a circle, or an ellipse.

### Another Embodiment of Invention

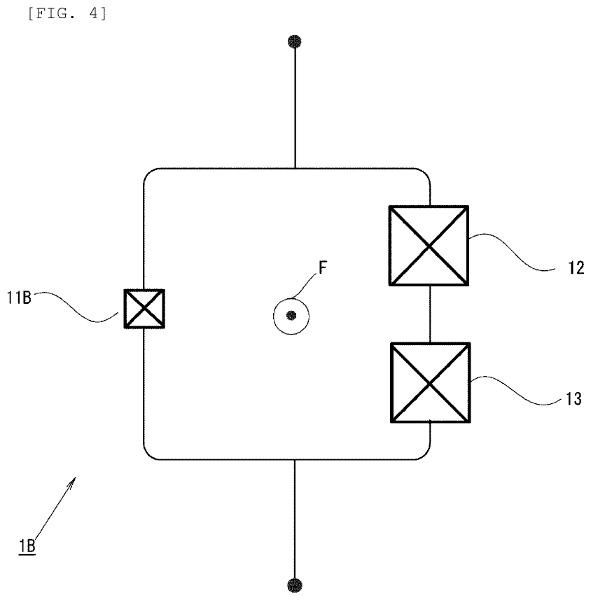

FIG. 4 is a diagram schematically showing a structure of a large-area junction magnetic flux type superconducting quantum bit 1B according to another embodiment of the invention. The large-area junction magnetic flux type superconducting quantum bit 1B has a form in which the magnetic flux F penetrates a loop formed by three Josephson junctions of a first Josephson junction 11B, the second Josephson junction 12, and the third Josephson junction 13, and this is the same as the structure of the large-area junction magnetic flux type superconducting quantum bit 1A according to the embodiment. In addition, the junction cross-sectional area of the second Josephson junction 12 and the junction cross-sectional area of the third Josephson junction 13 are the same as those of the large-area junction magnetic flux type superconducting quantum bit 1A according to the embodiment. However, an a junction ratio between the cross-sectional area of the first Josephson junction 11A and the cross-sectional areas of the second Josephson junction 12 and the third Josephson junction 13 and the value of B, which is a ratio of the magnetic flux type superconducting quantum bit to the Josephson junction cross-sectional area, are different from those of the large-area junction magnetic flux type superconducting quantum bit 1A according to the embodiment.

Various numerical values such as a size and characteristics of the large-area junction magnetic flux type superconducting quantum bit 1B according to the embodiment of the invention will be described. By appropriately adjusting the three values of the α junction ratio, the junction area S, and the Josephson critical current density J_{C}, it is possible to maintain the high anharmonicity and implement the long coherence time. In the embodiment, in order to improve the magnetic flux noise resistance, α=0.407, and the area of the two Josephson junctions having equal areas is 1.93 μm². Considering that the junction area of the normal magnetic flux type superconducting quantum bit is smaller than 0.25 μm², the junction area is seven times or more (β≥7: β is a ratio to the Josephson junction cross-sectional area of the magnetic flux type superconducting quantum bit).

By separately adjusting the Josephson critical current density J_{C}, the large-area junction magnetic flux type superconducting quantum bit 1B according to the embodiment of the invention to which the element size, the α junction ratio, and the junction area S described above are given has the characteristics that the minimum junction area is 0.79 μm², the critical current density is 6.77 A/cm², the anharmonicity is 453 MHz, and the quantum bit energy change (the smaller the change, the higher the coherence) with respect to the magnetic flux fluctuation which is an index of the magnetic flux noise resistance affecting the coherence time is 4.65 MHz. It can be seen that the magnetic flux noise resistance is improved while the anharmonicity is impaired compared to 1A. In addition, since the large shunt capacitor having a side of several tens to several 100 μm as in the shunt-equipped magnetic flux type superconducting quantum bit is not necessary, it can be seen that the footprint can be significantly reduced.

### Still Another Embodiment of Invention

Although not illustrated, various numerical values such as a size and characteristics of a large-area junction magnetic flux type superconducting quantum bit 1C according to still another embodiment of the invention will be described. In the embodiment, in order to improve the magnetic flux noise resistance, α=0.437 is set, and the area of the two Josephson junctions having equal areas is 1.80 μm², which is seven times or more the junction area of the normal magnetic flux type superconducting quantum bit (β≥7: β is the ratio to the Josephson junction cross-sectional area of the magnetic flux type superconducting quantum bit).

By separately adjusting the Josephson critical current density J_{C}, the large-area junction magnetic flux type superconducting quantum bit 1C according to the embodiment of the invention to which the element size, the α junction ratio, and the junction area S described above are given has the characteristics that the minimum junction area is 0.79 μm², the critical current density is 9.3 A/cm², the anharmonicity is 630 MHz, and the quantum bit energy change (the smaller the change, the higher the coherence) with respect to the magnetic flux fluctuation which is an index of the magnetic flux noise resistance affecting the coherence time is 9.42 MHz. It will be understood that Embodiment 1C is a balance type in which importance is placed on both the anharmonicity and the magnetic flux noise resistance as an intermediate between Embodiment 1A and Embodiment 1B.

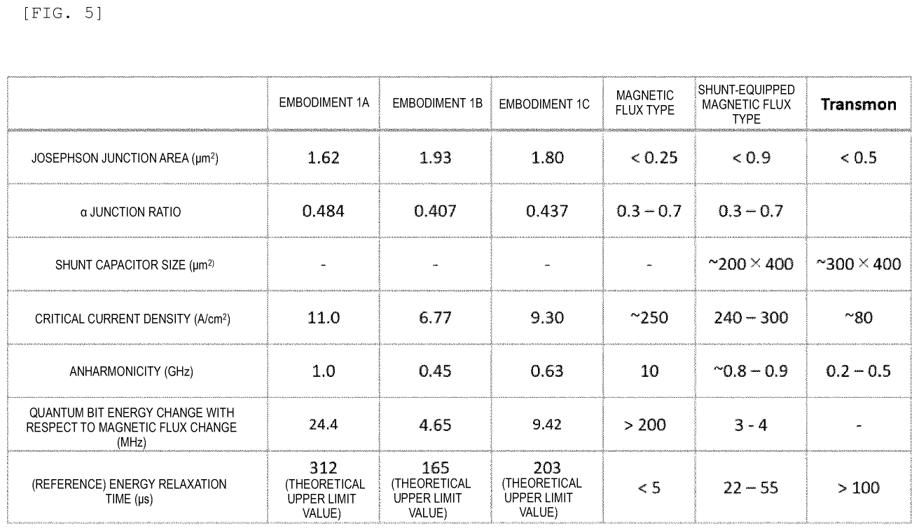

Differences in the characteristics between the embodiments (1A, 1B, and 1C) of the invention and the magnetic flux type superconducting quantum bit in the related art, the shunt-equipped magnetic flux type superconducting quantum bit, and Transmon which is a shunt-equipped charge type superconducting quantum bit will be studied. A table shown in FIG. 5 is a characteristic comparison table of these various superconducting quantum bits.

First, since there is no shunt capacitor on an order of 10,000 μm², it can be understood that the invention greatly contributes to a reduction in the footprint and a high density. Transmon and the shunt-equipped magnetic flux type superconducting quantum bits aim to improve an energy relaxation time even at an expense of high density, but the embodiments of the invention, although being theoretical upper limit values, are all superior to these energy relaxation times. The anharmonicity shows a value comparable to that of the shunt-equipped magnetic flux type evaluated to be more advantageous than Transmon. As described above, it will be understood that the embodiments of the invention are comprehensively superior to Transmon and the shunt-equipped magnetic flux type superconducting quantum bits.

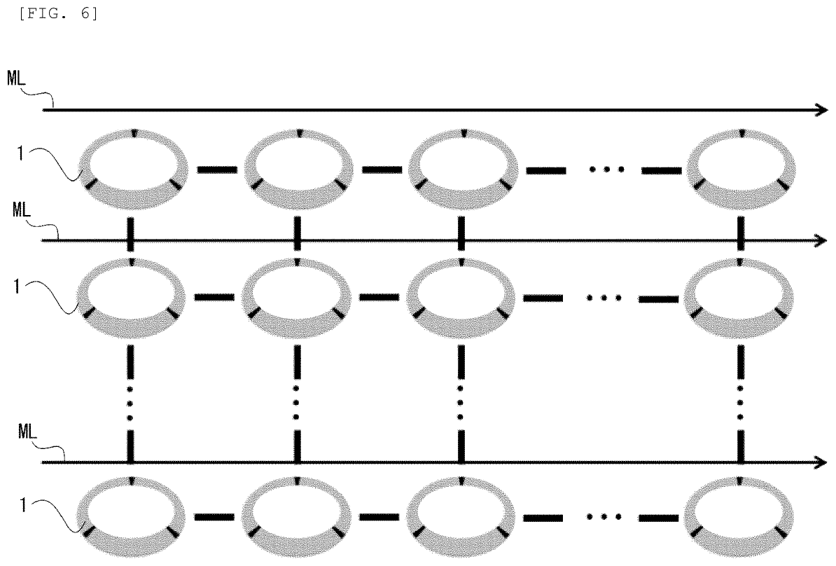

FIG. 6 shows a superconducting quantum computer equipped with a large-area junction magnetic flux type superconducting quantum circuit element according to an embodiment of the invention (superconducting quantum computer). A large-area junction magnetic flux type superconducting quantum circuit element 1 is disposed along a microwave control and readout line ML. Since a sufficient coherence time is achieved and the anharmonicity is also ensured, it is possible to reduce an error occurrence probability by simply adjusting control parameters such as an intensity and frequency of microwaves.

As described above, large-area junction magnetic flux type superconducting quantum circuit elements (large-area junction magnetic flux type superconducting quantum bits) according to the embodiments of the invention are described in detail with reference to the drawings, but specific configurations are not limited to the embodiments, and the invention includes a change in design or the like without departing from the gist of the invention.

In particular, the α junction ratio, the junction area S, and the Josephson critical current density J_{C} can be freely designed by appropriately adjusting the α junction ratio, the junction area S, and the Josephson critical current density J_{C} such that improvement of the coherence time is emphasized, improvement of the anharmonicity is emphasized, or both of them are emphasized, and this contributes to further expansion of the utilization technology in the field of computers in the future.

Also in the charge type superconducting quantum bit, there is an idea of improving the coherence time by focusing on the junction cross-sectional area. However, when an attempt is made to improve the coherence time, the anharmonicity is significantly impaired, and the coherence time and the anharmonicity are in a trade-off relationship. The invention provides a completely new element that overcomes such a trade-off relationship, achieves both the improvement in the coherence time and the improvement in the anharmonicity, has a small footprint, can achieve high density and be manufactured at low cost, and solves at once various problems of a superconducting quantum bit. It should be sufficiently understood that the invention is significant.

### REFERENCE SIGNS LIST

1A: large-area junction magnetic flux type superconducting quantum bit (large-area junction magnetic flux type superconducting quantum circuit element)
1B: large-area junction magnetic flux type superconducting quantum bit (large-area junction magnetic flux type superconducting quantum circuit element)
11A: first Josephson junction
11B: first Josephson junction
12: second Josephson junction
13: third Josephson junction
2: shunt-equipped magnetic flux type superconducting quantum bit
21: first Josephson junction
22: second Josephson junction
23: third Josephson junction
3: magnetic flux type superconducting quantum bit
31: first Josephson junction
32: second Josephson junction
33: third Josephson junction
F: magnetic flux

1. A large-area junction magnetic flux type superconducting quantum circuit element, wherein
the large-area junction magnetic flux type superconducting quantum circuit element is a superconducting quantum circuit element,
the superconducting quantum circuit element is based on a magnetic flux type superconducting quantum circuit element which has three Josephson junctions in one loop and in which an α junction ratio is introduced, the α junction ratio indicating that an area of one Josephson junction among the three Josephson junctions is α times an area of the other two Josephson junctions having equal areas, and
a junction cross-sectional area of each of the three Josephson junctions is set to be large as β times a junction cross-sectional area of the magnetic flux type superconducting quantum circuit element as a base while maintaining the α junction ratio, thereby improving a coherence time,
where 0.3≤α≤0.7, and 2≤β≤200.

2. The large-area junction magnetic flux type superconducting quantum circuit element according to claim 1, wherein
an area of each of the three Josephson junctions is set to be 0.5 μm² or more and 50.0 μm² or less.

3. The large-area junction magnetic flux type superconducting quantum circuit element according to claim 1, wherein
when it is assumed that a shunt-equipped magnetic flux type superconducting quantum circuit element to which a shunt capacitor is added is set to improve the coherence time of the magnetic flux type superconducting quantum circuit element,
a junction cross-sectional area of each of the three Josephson junctions is set to be large enough to obtain a value of a combined capacitance equivalent to a combined capacitance of the shunt-equipped magnetic flux type superconducting quantum circuit element, and no shunt capacitor is actually added.

4. The large-area junction magnetic flux type superconducting quantum circuit element according to claim 1, wherein
the α junction ratio, an area S of the two Josephson junctions having equal areas, and a Josephson critical current density J_{C} are adjusted to prioritize improvement of anharmonicity.

5. The large-area junction magnetic flux type superconducting quantum circuit element according to claim 1, wherein
the α junction ratio, an area S of the two Josephson junctions having equal areas, and a Josephson critical current density J_{C} are adjusted to prioritize improvement of the coherence time.

6. A superconducting quantum computer comprising:
the large-area junction magnetic flux type superconducting quantum circuit element according to claim 1.
